(19) United States
(12) Patent Application Publication
(10) Pub. No.: US 2014/0054078 A1
(43) Pub. Date: Feb. 27, 2014

(54) Lead Frame Base Plate for Light Emitting Device and Manufacturing Method of Light Emitting Device Using the Same

(71) Applicant: WOOREE E&L CO., LTD., Gyeonggi-do (KR)

(72) Inventors: Ho Seong Bae, Gyeonggi-do (KR); Byung Nyun Im, Gyeonggi-do (KR); Yong Jun Lee, Gyeonggi-do (KR)

(73) Assignee: WOOREE E&L CO., LTD., Gyeonggi-do (KR)

(21) Appl. No.: 13/971,908

(22) Filed: Aug. 21, 2013

(30) Foreign Application Priority Data
Aug. 21, 2012 (KR) 10-2012-0091107

(51) Int. Cl. H01L 33/62

(52) U.S. Cl. CPC H01L 33/62
USPC 174/261; 438/26

(57) ABSTRACT

Disclosed is a lead frame base plate for a light emitting device, the base plate including: one or more lead frame areas respectively including a plurality of lead frames repeated in a first direction, the lead frame areas being arranged in parallel to be spaced apart from each other in a second direction intersecting with the first direction; and two or more openings extended in the first direction at both sides of each lead frame area so that the plurality of lead frames may be divided through a single direction sawing process performed in the second direction.

### CROSS-REFERENCE TO RELATED APPLICATIONS

This application claims the benefit and priority of Korean Patent Application No. 10-2012-0091107, filed Aug. 21, 2012. The entire disclosure of the above application is incorporated herein by reference.

### FIELD

The present disclosure relates to a light emitting device, and more specifically, to a lead frame base plate for a light emitting device and a method of manufacturing the light emitting device using the same.

### BACKGROUND

This section provides background information related to the present disclosure which is not necessarily prior art.

Recently, light emitting devices using a light emitting diode (hereinafter, referred to as an LED) as a light emitting element are gradually generalized. Since the LED has excellent optical efficiency and can be miniaturized, it is frequently configured in the form of a package and diversely used as backlight of a display device, a light source of a lighting apparatus and the like. A light emitting device using the LED as a light emitting element may provide uniform illuminance by assembling a plurality of LED chips in a certain arrangement rule. Generally, the LED chips configured as a package, mounted on a printed circuit board and electrically connected to one another are connected to other electrical systems.

FIG. 1 is a view showing an example of an LED package according to the prior art, and the LED package 10 includes a light emitting element 15, a housing 25 having a cavity 23 open upward to accommodate the light emitting element 15, a lead frame 35 combined with the housing 25 to support the light emitting element 15 and apply power, and a sealing part 45 sealing the light emitting element 15. The lead frame 35 has lead parts 36 and 37 protruding toward outside of the housing 25 from both opposing ends of the lead frame 35.

FIG. 2 is a view illustrating a process of manufacturing an LED package using a thermoplastic resin according to the prior art, and the LED package is manufactured in a method of manufacturing a plurality of LED packages in a single process.

In manufacturing the LED package using a thermoplastic resin, a lead frame base frame 50 including a plurality of lead frames 35 spaced apart from each other by a predetermined distance is used, and the housing 25 is formed in a structure integrated with an individual lead frame 35 by performing injecting molding on the lead frame base plate 50 using a thermoplastic resin. Subsequently, an LED chip 15 (see FIG. 1) used as a light emitting element is mounted on each lead frame 35 and electrically connected. Then, the sealing part 45 (see FIG. 1) is formed to seal the LED chip and penetrate light by dropping and hardening a sealant, i.e., a mixture of a fluorescent substance for implementing a specific color and a resin of a transparent material, in the cavity 23 (see FIG. 1) of the housing 25. Subsequently, an independent LED package 10 is completed in a structure having lead parts 36 and 37 protruding from both ends of the lead frame 35 as shown in FIG. 1 by cutting the lead parts 36 and 37 corresponding to both ends of the lead frame 35 and exposed to outside of the housing 25 by the unit of a package in a method such as trimming.

The LED package using a thermoplastic resin as described above has a problem in that if it is used for an extended period of time, reliability of the LED package is lowered and the lifespan of the LED package is limited due to the reasons such as deformation of the thermoplastic resin forming the housing. Accordingly, LED package is inappropriate for a high-efficiency high-power light emitting device.

Recently, thermosetting resin is increased to be used instead of the thermoplastic resin in order to provide a high-efficiency high-power light emitting device with high product reliability.

FIG. 3 is a view illustrating a process of manufacturing an LED package using a thermosetting resin according to the prior art, and FIG. 4 is a view showing an LED package manufactured through the manufacturing process of FIG. 3.

The LED package using a thermosetting resin is also manufactured in a method of manufacturing a plurality of LED packages in a single process, like the LED package using a thermoplastic resin. However, as shown in FIG. 3, the LED package using a thermosetting resin is manufactured using a mapping type lead frame base plate 50′ of high integrity having a structure connecting a plurality of lead frames 35′ in the vertical and horizontal directions.

Since the cost of material of the thermosetting resin is considerably high and the molding process is very difficult and requires a lot of time compared with the thermoplastic resin, it is undesirable to use the lead frame base plate 50 of a sparse structure as is as shown in FIG. 2. That is, a lead frame base plate 50′ of high integrity is used to minimize the thermosetting resin thrown away in the process of cutting the lead frame base plate 50 into individual LED packages after performing injection molding using the thermosetting resin.

By performing injection molding using a thermosetting resin on the mapping type lead frame base plate 50′, a plurality of LED packages 10′ is formed in a structure integrating a plurality of lead frames 35′ and a plurality of housings 25′ to be one to one correspondent to each other, and an LED package block 60 integrating the plurality of LED packages 10′ is formed. Subsequently, an LED chip 15′ used as a light emitting element is mounted on each lead frame 35′ and electrically connected. Then, a sealing part 45′ is formed to seal the LED chip 15′ and penetrate light by dropping and hardening a sealant, i.e., a mixture of a fluorescent substance for implementing a specific color and a resin of a transparent material, in the cavity 23′ of each housing 25′.

In this state, individual LED packages are repeatedly connected to adjacent LED packages in the vertical and horizontal directions. Accordingly, the LED package block 60 cannot be separated into individual LED packages by cutting only the lead parts in a trimming method, unlike the LED package using a thermoplastic resin, and an independent LED package 10′ as shown in FIG. 4 is completed by performing a two-way sawing process in the horizontal and vertical directions.

However, in the LED package 10′ using a thermosetting resin like this, each lead frame 35 does not have lead parts 36 and 37 (see FIG. 1) protruding from both ends, unlike the LED package 10 using a thermoplastic resin as shown in FIG. 1. Accordingly, since electrical connection through the protruding lead parts is not allowed, existing test equipment used for testing optical characteristics of an LED package using a thermoplastic resin cannot be commonly used in a test such as an optical characteristic test. In addition, since electrical connection implemented by soldering the protruding lead parts cannot be accomplished when, for example, the LED package is mounted on an array bar or the like in order to configure a lighting apparatus, the connection state between the solder and the lead parts cannot be confirmed with naked eyes.

### SUMMARY

The problems to be solved will be described in the latter part of the detailed description.

This section provides a general summary of the disclosure and is not a comprehensive disclosure of its full scope or all of its features.

To this end, the present disclosure provides a lead frame base plate for a light emitting device, including one or more lead frame areas respectively including a plurality of lead frames repeated in a first direction, the lead frame areas being arranged in parallel to be spaced apart from each other in a second direction intersecting with the first direction; and two or more openings extended in the first direction at both sides of each lead frame area so that the plurality of lead frames may be divided through a single direction sawing process performed in the second direction.

In addition, the present disclosure provides a method of manufacturing a light emitting device, including a step of providing a lead frame base plate including: one or more lead frame areas respectively including a plurality of lead frames repeated in a first direction, the lead frame areas being arranged in parallel to be spaced apart from each other in a second direction intersecting with the first direction; and two or more openings extended in the first direction at both sides of each lead frame area so that the plurality of lead frames may be divided through a single direction sawing process performed in the second direction; an injection molding step of forming an LED package block having a plurality of LED packages integrated in a structure repeating the plurality of LED packages in the first direction, the LED package integrating a lead frame and a housing and having lead parts protruding from both ends of a lead frame adjacent to the opening, by performing injection molding on the lead frame areas using a thermosetting resin, but not on both side end portions of each lead frame area adjacent to the opening; and a sawing step of dividing the LED package block into a plurality of independent LED packages by cutting the LED package block along a border line of the LED packages in the second direction intersecting with the first direction.

### BRIEF DESCRIPTION OF THE DRAWINGS

FIG. 1 is a view showing an example of an LED package according to the prior art.

FIG. 2 is a view illustrating a process of manufacturing an LED package using a thermoplastic resin according to the prior art.

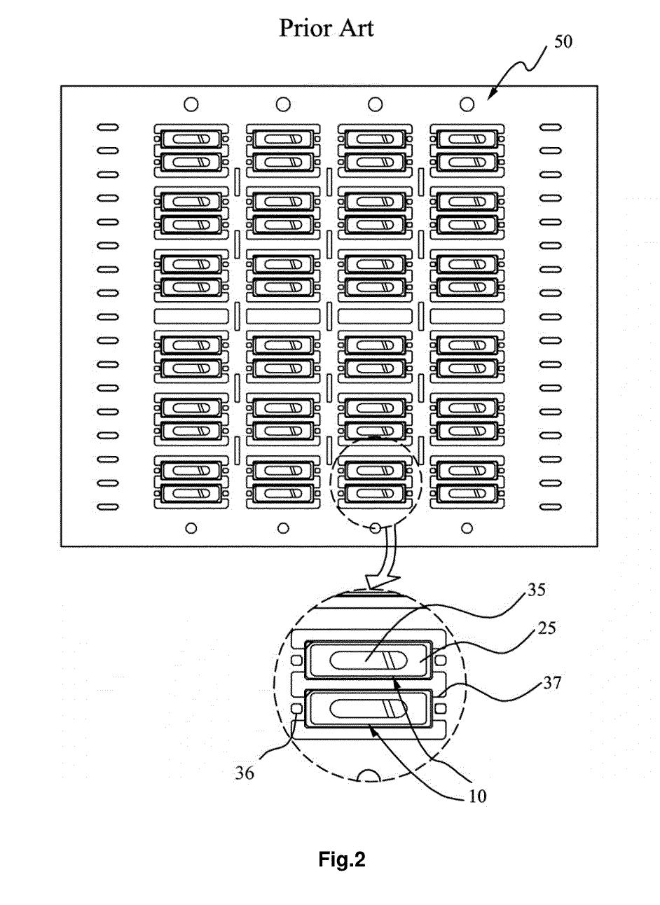

FIG. 3 is a view illustrating a process of manufacturing an LED package using a thermosetting resin according to the prior art.

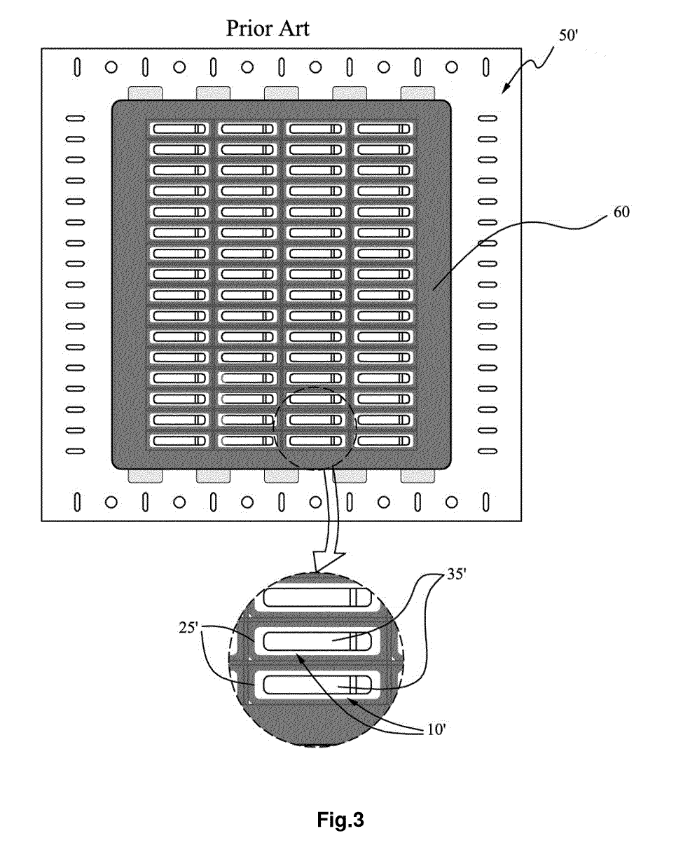

FIG. 4 is a view showing an LED package manufactured through the manufacturing process of FIG. 3.

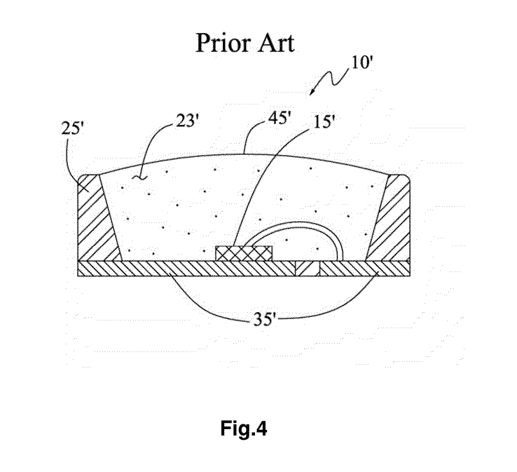

FIG. 5 is a view showing a lead frame base plate according to a first embodiment of the present disclosure.

FIG. 6 is a view illustrating a process of manufacturing a light emitting device using a lead frame base plate according to a first embodiment of the present disclosure.

FIG. 7 is a view showing an LED package manufactured using a lead frame base plate according to the present disclosure.

FIG. 8 is a view showing a lead frame base plate according to a second embodiment of the present disclosure.

FIG. 9 is a view illustrating an example of a process of manufacturing a light emitting device using a lead frame base plate according to a second embodiment of the present disclosure.

FIG. 10 is a view illustrating another example of a process of manufacturing a light emitting device using a lead frame base plate according to a second embodiment of the present disclosure.

### BRIEF DESCRIPTION OF REFERENCE NUMBERS

| | |
|---|---|
| 100: LED package | 101: First direction |
| 103: Second direction | 105: Lead frame |
| 107: First electrode | 109: Second electrode |
| 110, 110′: Lead frame area | 111: Border line |
| 113: Lead frame section | 115: LED chip |
| 117: Small opening | 120: Opening |
| 123: Cavity | 125: Housing |
| 136, 137: Lead part | 145: Sealing part |
| 150, 150′: Lead frame base plate | |

160, 160′, 160″: LED package block

### DETAILED DESCRIPTION

The present disclosure will now be described in detail with reference to the accompanying drawings.

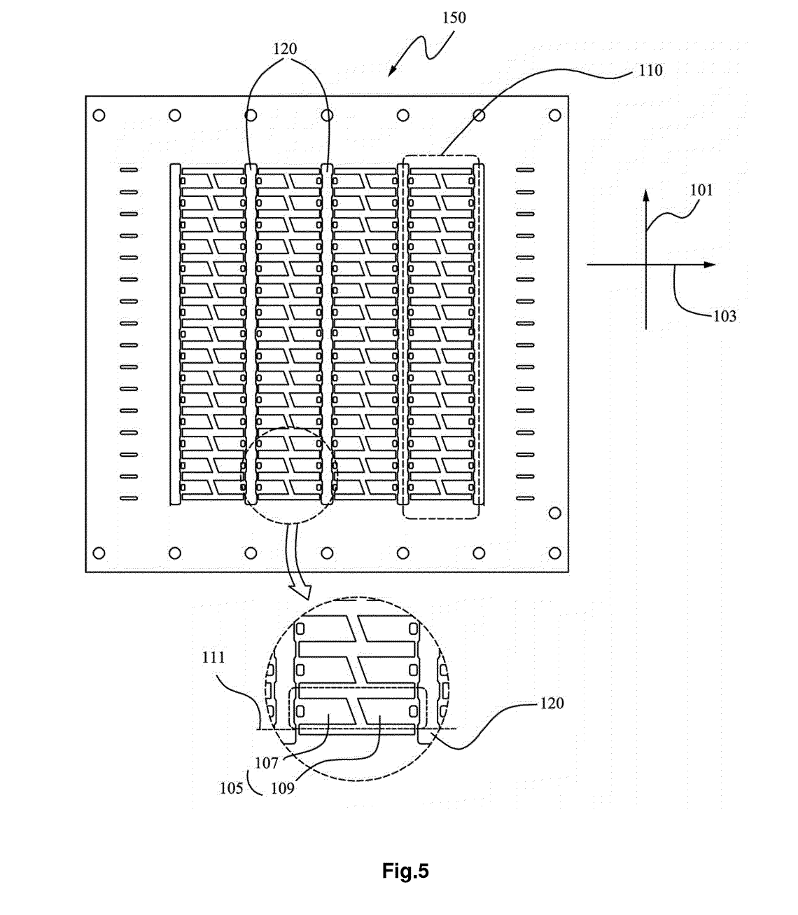

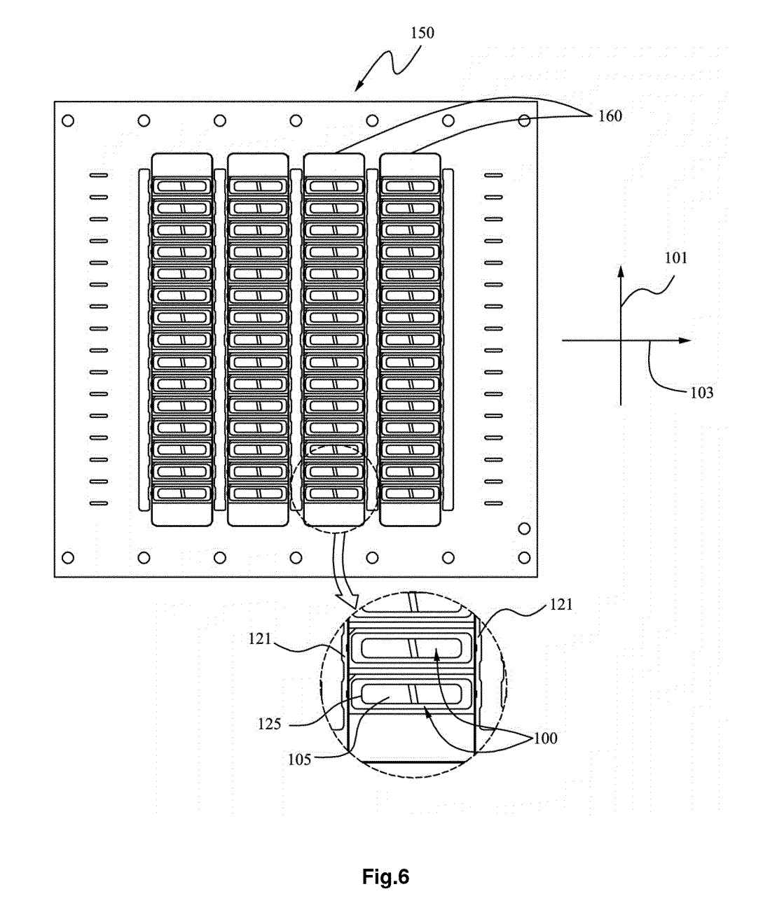

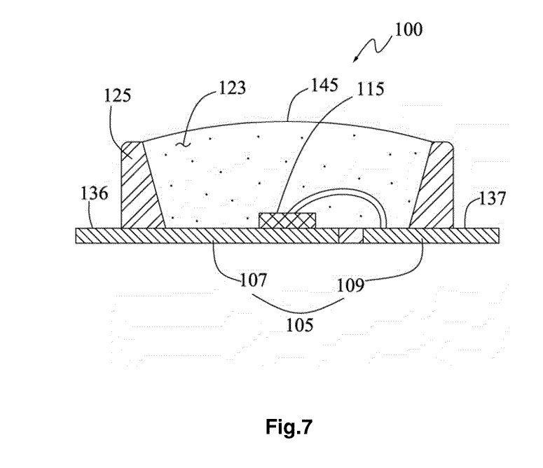

FIG. 5 is a view showing a lead frame base plate according to a first embodiment of the present disclosure. FIG. 6 is a view illustrating a process of manufacturing a light emitting device using a lead frame base plate according to a first embodiment of the present disclosure. FIG. 7 is a view showing an LED package manufactured using a lead frame base plate according to the present disclosure.

Referring to FIG. 5, although it is not limited to the followings, the lead frame base plate 150 for manufacturing a light emitting device includes four lead frame areas 110 respectively having a plurality of lead frames 105 repeated in a first direction, and five openings 120 extended in the first direction 101 at positions between the lead frame areas 110 and at one side of lead frame areas 110 placed at both side ends. That is, the openings 120 are positioned at both sides of each lead frame area 110 from the viewpoint of an individual lead frame area 110. The openings 120 like this allow the plurality of lead frames 105 included in the lead frame area 110 to be divided only through a single direction sawing process performed in a second direction 103.

Here, the first direction 101 is defined as the vertical direction on the drawings, and the second direction 103 is defined as the horizontal direction intersecting with the first direction 101.

Each of the lead frame areas 110 includes a plurality of lead frames 105 repeated in the first direction, and accordingly, the lead frame area 110 is provided in an integrated form since the plurality of lead frames 105 is directly connected without a space between the lead frames. However, since the openings 150 are provided, the lead frames 105 are not directly connected to the lead frames 105 included in adjacent lead frame areas 110 and arranged to be spaced apart from the lead frames 105 included in the adjacent lead frame areas 110 by a distance approximately corresponding to the second direction width of the opening 120. The lead frame 105 is a unit part for constructing a single LED package 100, including a first electrode 107 and a second electrode 109 respectively arranged on the left and right sides in the second direction 103.

The opening 120 is extended toward both ends in the first direction 101 to go beyond the imaginary border lines 111 formed at the outer sides of the lead frames 105 positioned at both ends of the adjacent lead frame areas 110 in the first direction 101. This is to efficiently carry out the cutting work by preventing both ends of the opening 120 in the first direction 101 from being configurationally interfered with a cutting tool such as a blade (not shown) used as a cutting means when a sawing process is performed in the process of manufacturing a light emitting device, and this will be described below.

Hereinafter, a method of manufacturing an LED package type light emitting device using a lead frame base plate according to a first embodiment will be described with reference to FIGS. 6 and 7.

Since the lead frame base plate 150 including a plurality of lead frames 105 is used for manufacturing a lighting emitting device, a plurality of LED packages 100 may be manufactured in a single process.

First, an injection molding process is performed on the lead frame base plate 150 using a thermosetting resin. The injection molding process is performed to form an LED package block 160 on each lead frame area 110, and a plurality of LED packages 100 is integrated in the LED package block 160 in a structure repeating the LED packages in the first direction 101. Then, the injection molding process may be simultaneously or sequentially performed on all the lead frame areas 110 included in the lead frame base plate 150.

More specifically, the injection molding is performed on the lead frame areas 110 but not on both side end portions 121 of each lead frame area 110 adjacent to the opening 120. Accordingly, each LED package 100 is configured in the form of integrating the lead frame 105 and the housing 125 and having lead parts 136 and 137 protruding from both ends of the lead frame 105 adjacent to the opening 120.

The LED package 100 may have a complete form by performing a process of mounting and electrically connecting the LED chip 115 used as a light emitting element on each of the lead frames 105 and a process of forming a sealing part 145 around the LED chip 115 using a sealant, i.e., a mixture of a fluorescent substance for implementing a specific color and a resin of a transparent material, after the injection molding process, before performing the sawing process described below, in a manner the same as that of the prior art. As a specific example, as shown in FIG. 7, the LED chip 115 is mounted on the left side first electrode 107 configuring the lead frame 105, and the LED chip 115 is connected to the first electrode 107 and the second electrode 109 in a wire bonding method. Then, the sealing part 145 is completed around the LED chip 115 by dropping and hardening a liquid sealant, i.e., a mixture of a fluorescent substance and a transparent resin, in the cavity 123 of the housing 125.

Subsequently, a completed LED package 100 is provided as shown in FIG. 7 by performing a sawing process for dividing the LED package block 160 including a plurality of LED packages 100 into a plurality of independent LED packages by cutting the LED package block 160 along the border line 111 of the LED package 100 in the second direction 104 intersecting with the first direction 101.

The sawing process is performed in a method of, for example, moving a cutting means (not shown), having a plurality of blades arranged at intervals corresponding to the first direction width of the LED package 100, in the second direction 103 and cutting the LED package block 160. At this point, the cutting means consecutively cuts all the LED package blocks 160 positioned on the moving path.

Meanwhile, as described above, since the opening 120 is extended toward both ends in the first direction 101 to go beyond the imaginary border lines 111 formed at the outer sides of the lead frames 105 positioned at both ends of the adjacent lead frame areas 110 in the first direction 101, both ends of the opening 120 in the first direction are spaced apart from the moving path of the blades configuring the cutting means, and accordingly, configuration interference between the blades and both ends of the opening 120 does not occur in the sawing process, and thus the sawing process can be performed smoothly.

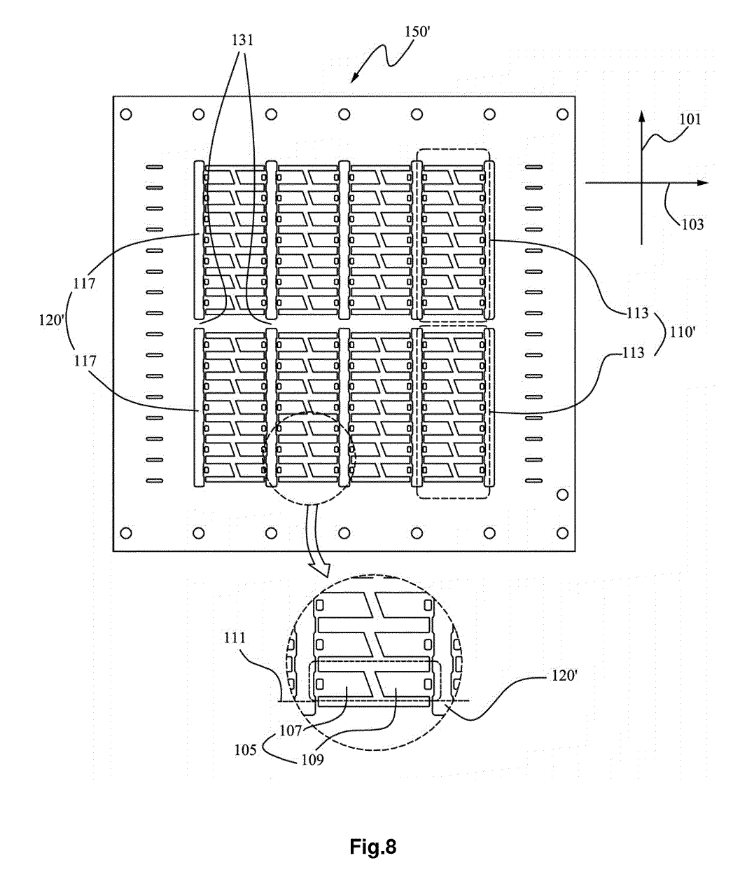

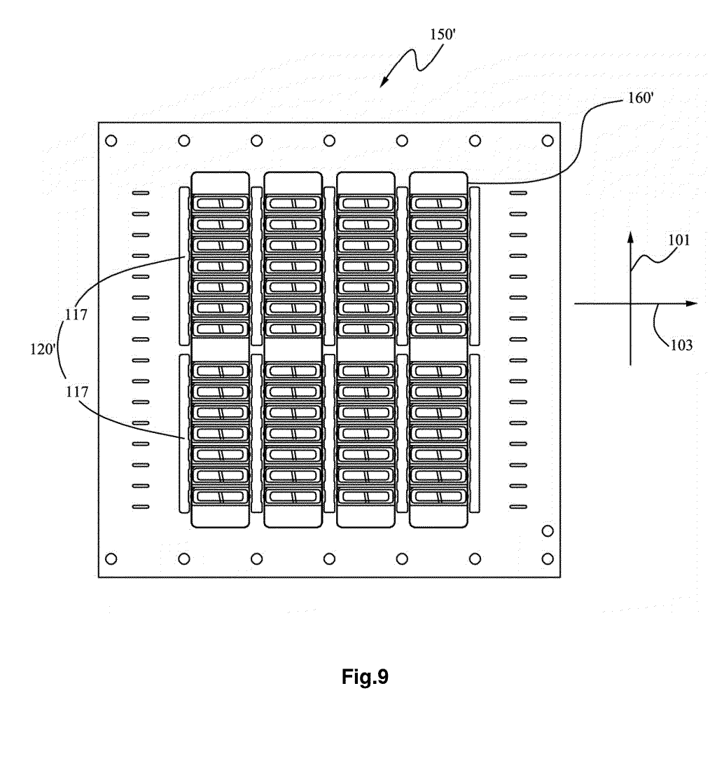

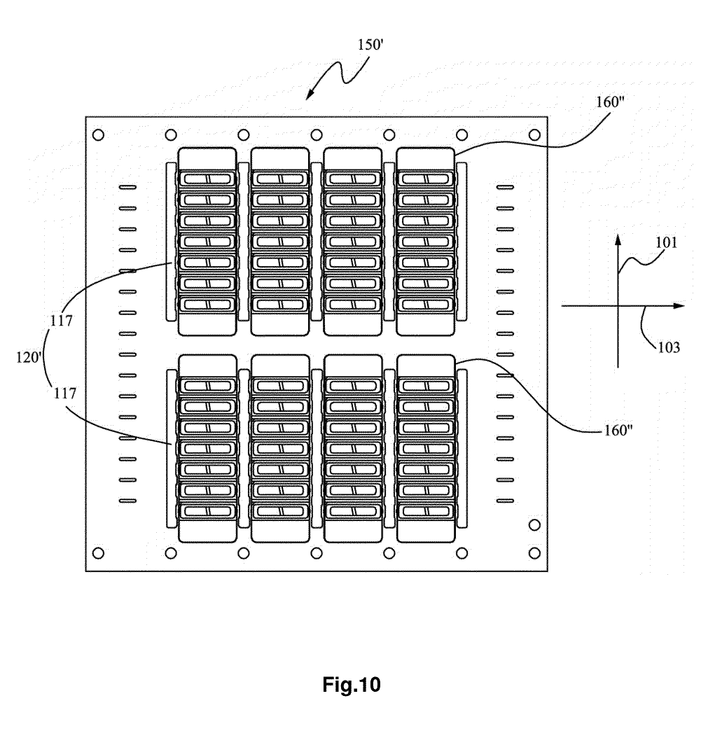

FIG. 8 is a view showing a lead frame base plate according to a second embodiment of the present disclosure. FIG. 9 is a view illustrating an example of a process of manufacturing a light emitting device using a lead frame base plate according to a second embodiment of the present disclosure. FIG. 10 is a view illustrating another example of a process of manufacturing a light emitting device using a lead frame base plate according to a second embodiment of the present disclosure.

Referring to FIG. 8, the lead frame base plate 150′ for manufacturing an LED package type light emitting device includes four lead frame areas 110′ respectively divided into two lead frame sections 113 and five openings 120′ respectively divided into two small openings 117 in correspondence to the two lead frame sections 113, unlike the lead frame base plate 150 of the first embodiment shown in FIG. 5.

The reason why the lead frame areas 110′ and the openings 120′ are divided as described above is that although the integrity level of the lead frames 105 is lowered, the capability of maintaining the shape of the lead frame base plate 150′ is improved, and generation of defective products may be reduced in the process of manufacturing a light emitting device. That is, if each of the openings 120′ is divided into two small openings 117 in the lead frame base plate 150′ that can be easily bent as the lead frame base plate 150′ is formed to be extremely thin, the portion between the two small openings 117 of the lead frame base plate 150′ connects adjacent lead frame areas 110′ to each other and connects the lead frame areas 110′ placed at both side ends to the outer surrounding area, and structural integrity such as preventing sagging down of the lead frame area 110′ may be improved. Accordingly, defects of products caused by sagging down of the lead frame area 110′ or the like may be effectively prevented.

Although the lead frame area 110′ is divided into two lead frame sections 113 and the opening 120′ is divided into two small openings 117 in this embodiment, they may be divided into further more lead frame sections and small openings as needed.

The small opening 117 is extended toward both ends in the first direction 101 to go beyond the imaginary border lines 111 formed at the outer sides of the lead frames 105 positioned at both ends of the adjacent lead frame areas 110 in the first direction 101, in a manner similar to that of the first embodiment. Such a small opening 117 is formed also to efficiently carry out the cutting work by preventing both ends of the small opening 117 in the first direction 101 from being configurationally interfered with a cutting tool such as blades used as a cutting means when a sawing process is performed in the process of manufacturing a light emitting device.

Hereinafter, a method of manufacturing an LED package type light emitting device using a lead frame base plate according to a second embodiment will be described with reference to FIGS. 9 and 10.

The process of manufacturing a light emitting device using a lead frame base plate 150′ according to a second embodiment is practically the same as the process of manufacturing a light emitting device package using a lead frame base plate 150 according to a first embodiment, except that the injection molding process may be performed in a somewhat different way, since the lead frame base plate 150′ according to the second embodiment includes lead frame areas 110′ respectively divided into two lead frame sections 113 and openings 120′ respectively divided into two small openings 117 in correspondence to the two lead frame sections 113, and therefore, overlapped descriptions will be omitted.

For example, the injection molding process may be performed to form one LED package block 160′ as shown in FIG. 9 regardless of dividing the lead frame area 110′ into two lead frame sections 113. As another example, the injection molding process may be performed to form two LED package blocks 160″ as shown in FIG. 10 in correspondence to dividing the lead frame area 110′ into two lead frame sections 113.

In addition, although the opening 120′ is divided into the two small openings 117, since the small opening 117 is also extended toward both ends in the first direction to go beyond the imaginary border lines formed at the outer sides of the lead frames 105 positioned at both ends of the adjacent lead frame areas 110 in the first direction 101 in correspondence to dividing the lead frame area 110′ into two lead frame sections 113, both ends of the small opening 117 in the first direction are spaced apart from the moving path of a cutting tool such as blades configuring a cutting means. Therefore, configuration interference between the blades and both ends of the opening 120 does not occur in the sawing process, and thus the sawing process can be performed smoothly.

The present disclosure provides a lead frame base plate for a light emitting device and a method of manufacturing the light emitting device using the same, which can be used for manufacturing an LED package having lead parts protruding from both ends of a lead frame, while providing a high integrity level appropriate for manufacturing the LED package using a thermosetting resin.

The lead frame base plate and a method of manufacturing a light emitting device using the same according to the present disclosure may be used for manufacturing an LED package using a thermosetting resin which is excellent from the aspect of reliability and lifespan of a product and appropriate for a high-efficiency high-power specification.

Specifically, since the lead frame base plate 150 or 150′ includes a plurality of lead frames 105 arranged at a high integrity level, the lead frame base plate and a method of manufacturing a light emitting device using the same according to the present disclosure may be used for manufacturing an LED package using a thermosetting resin, which is difficult to mold and needs a lot of time for molding.

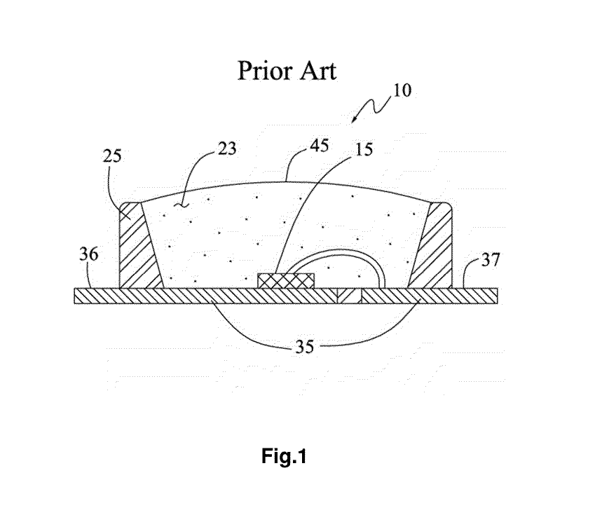

Further, since the lead frame base plate and a method of manufacturing a light emitting device using the same according to the present disclosure may be used for manufacturing an LED package 110 using a thermosetting resin, which includes lead parts 136 and 137 protruding from both ends of a lead frame as shown in FIG. 7, like an LED package 10 (see FIG. 1) using a thermoplastic resin according to the prior art, existing test equipment used for testing optical characteristics of an LED package using a thermoplastic resin may be commonly used in a test such as an optical characteristic test performed on a manufactured LED package, and when the LED package is mounted on an array bar or the like in order to configure a lighting apparatus, electrical connection can be implemented in a method of soldering the protruding lead parts 136 and 137, and the connection state between the solder and the lead parts 136 and 137 can be easily confirmed with naked eyes.

Furthermore, since the lead frame base plate 150 or 150′ is provided with openings 120 or 120′, the lead frame base plate and a method of manufacturing the light emitting device using the same according to the present disclosure may divide the lead frame base plate 150 or 150′ into independent LED packages 100 only through a single direction sawing process performed in the second direction 103, and since the sawing process is simplified, the working time may be reduced, and, in addition, lifespan of a cutting tool such as blades used in the sawing process may be increased.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A lead frame base plate for a light emitting device, the lead frame base plate comprising:
one or more lead frame areas respectively including a plurality of lead frames repeated in a first direction, the lead frame areas being arranged in parallel to be spaced apart from each other in a second direction intersecting with the first direction; and
two or more openings extended in the first direction at both sides of each lead frame area so that the plurality of lead frames may be divided through a single direction sawing process performed in the second direction.

2. The lead frame base plate according to claim 1, wherein the opening is extended toward both ends in the first direction to go beyond border lines formed at outer sides of lead frames positioned at both ends of adjacent lead frame areas in the first direction.

3. The lead frame base plate according to claim 2, wherein each of the lead frame areas is divided into two or more lead frame sections, and each of the lead frame sections includes a plurality of lead frames.

4. The lead frame base plate according to claim 3, wherein each of the openings is divided into two or more small openings in correspondence to the two or more lead frame sections.

5. The lead frame base plate according to claim 4, wherein the small opening is extended toward both ends in the first direction to go beyond border lines formed at outer sides of lead frames positioned at both ends of corresponding lead frame sections in the first direction.

6. A method of manufacturing a light emitting device, the method comprising:
a step of providing a lead frame base plate including: one or more lead frame areas respectively including a plurality of lead frames repeated in a first direction, the lead frame areas being arranged in parallel to be spaced apart from each other in a second direction intersecting with the first direction; and two or more openings extended in the first direction at both sides of each lead frame area so that the plurality of lead frames may be divided through a single direction sawing process performed in the second direction;
an injection molding step of forming an LED package block having a plurality of LED packages integrated in a structure repeating the plurality of LED packages in the first direction, the LED package integrating a lead frame and a housing and having lead parts protruding from both ends of a lead frame adjacent to the opening, by performing injection molding on the lead frame areas using a thermosetting resin, but not on both side end portions of each lead frame area adjacent to the opening; and
a sawing step of dividing the LED package block into a plurality of independent LED packages by cutting the LED package block along a border line of the LED packages in the second direction intersecting with the first direction.

7. The method according to claim 6, wherein the injection molding step is simultaneously performed on two or more lead frame areas and forms the LED package block distinguished by a unit of a lead frame area.

8. The method according to claim 7, wherein each of the lead frame areas is divided into two or more lead frame sections, and the injection molding step forms the LED package block by the unit of the lead frame area including two of more lead frame sections.

9. The method according to claim 7, wherein each of the lead frame areas is divided into two or more lead frame sections, and the injection molding step forms the LED package block by a unit of the divided lead frame section.

10. The method according to claim 6, wherein the sawing step cuts the LED package block in a method of moving a cutting means along the second direction, the cutting means having a plurality of blades arranged at intervals corresponding to a first direction width of each LED package.

11. The method according to claim 10, wherein the sawing step consecutively cuts all LED package blocks positioned on a moving path of the cutting means.
